(19) United States
(12) Patent Application Publication
(10) Pub. No.: US 2010/0270070 A1
(43) Pub. Date: Oct. 28, 2010

(54) ISOLATION

(76) Inventor: Philip Bradley, Birmingham (GB)

Correspondence Address: MERCHANT & GOULD PC, P.O. BOX 2903, MINNEAPOLIS, MN, 55402-0903, US

(21) Appl. No.: 12/295,140

(22) PCT Filed: Mar. 28, 2007
(86) PCT No.: PCT/GB2007/001152

§ 371 Date: Jun. 28, 2010

(30) Foreign Application Priority Data
Mar. 28, 2006 (GB) 0606108.9

(51) Int. Cl. H05K 9/00; B65B 5/04

(52) U.S. Cl. 174/378; 174/377; 53/467

(57) ABSTRACT

An apparatus and method is provided for isolating a telecommunication device by introducing the device to a first container part of a container, the container having a first container part and a second container part, the first container part being accessed from the second container part through a first seal, the first seal having an open state and a closed state, the second container part being accessed from the environment around the container through a second seal, the second seal having an open state and a closed state. The first container part and second container part, at least in part are formed of a flexible electrical conductor to provide electromagnetic shielding. The method includes the device being introduced to the first container part of the container with the first seal and the second seal in the open state, one or both of the first and second seals then being placed in the closed state to isolate the device from external electromagnetic radiation.

This invention is concerned with improvements in and relating to isolation, particularly, but not exclusively, the electromagnetic isolation of mobile telecommunication devices.

As mobile telecommunication devices are increasingly used in everyday life, so they are increasingly used in criminal activities or circumstances of interest to law enforcement authorities. When a mobile telecommunication device is found, there are benefits in isolating it from its surroundings so as to prevent communication from and to it. Existing containers provide varying degrees of isolation, but may not be fully effective. They also prevent subsequent desired communication with the device, for instance to interrogate it.

According to a first aspect of the invention we provide a container, the container comprising a first container part and a second container part, the first container part being accessed from the second container part through a first seal, the first seal having an open state and a closed state, the second container part being accessed from the environment around the container through a second seal, the second seal having an open state and a closed state, the first container part and second container part, at least in part being formed of an electrical conductor to provide electromagnetic shielding.

Preferably the container is a bag. The container may have a square or rectangular profile.

The first container part is preferably larger than the second container part. The first container part and second container part may have the same width. The first container part may be longer than the second container part. Preferably the first container part and/or second container part are wider than the length of a mobile telecommunication device, such as a mobile phone. Preferably the first container part is longer than the length of a mobile telecommunication device, such as a mobile phone.

Preferably the first seal is provided according to the third aspect of the invention and/or according to the fourth aspect of the invention. The first seal may include any of the features, options or possibilities provided for in the third aspect and/or in the fourth aspect

Preferably the first seal is provided at one end of the first container part. Preferably the first seal is provided at one end of the second container part.

Preferably the first seal provides electromagnetic shielding in the closed state.

Preferably the second seal is provided according to the third aspect of the invention and/or according to the fourth aspect of the invention. The second seal may include any of the features, options or possibilities provided for in the third aspect and/or in the fourth aspect

Preferably the second seal is provided at one end of the second container part, ideally the other end to the end of the second container part provided with the first seal.

Preferably the second seal provides electromagnetic shielding in the closed state.

Preferably the electrical conductor is flexible, at least in part. Preferably the electrical conductor provides electromagnetic shielding of at least 40 dB, more preferably of at least 50 dB and ideally of at least 60 dB. Preferably the first seal and/or second seal, in the closed state, provide electromagnetic shielding of at least 40 dB, more preferably of at least 50 dB and ideally of at least 60 dB.

The flexible electrical conductor may be a fabric, for instance a nylon fabric. The fabric may be kitted or woven. The flexible electrical conductor may be provided by coating a substrate, potentially non-conducting, with a conductor. The conductor may be or include silver or gold.

One or more edges of the first container part may be provided by a fold provided in a length of flexible conductor. One or more edges of the first container part may be provided by using stitches and/or adhesive to join two pieces of flexible conductor together. Preferably a section of conductor is folded across the seam in respect of one or more, and preferably all, the seams.

The first container part may be provided with one or more regions which have two, or more preferably three, layers of flexible conductor. One face of the first container part may be entirely provided with two layers, or more preferably three layers. One face of the first container part may be in part provided with two layers, or more preferably three, and in part provided with one layer, or more preferably two layers. Preferably the part provided with one layer, or more preferably two layers, is surrounded with parts provided with two layers, or more preferably three layers. The part provided with one layer may be centrally provided and/or cover an area which exceeds the width and/or length of a mobile telecommunication device, such as a mobile phone. One face of the first container part may be provided entirely with one layer, or more preferably two layers.

The first container part may be provided with an electrical connector. The electrical connector may pass through the first container part to the surrounding environment. The connector may be provided in the end of the first container part, preferably the end opposing the end provided with the first seal.

The electrical connector may be mounted on a rigid element, such as a plate. A part of the electrical connector may be sandwiched between a rigid element and another component, for instance a second rigid plate. One or two oval rigid plates may be provided. The flexible conductor may be mounted on a rigid element, for instance sandwiched between first and second plates.

The electrical connector may be mounted within a seam of the container. The electrical connector may be provided within a unit. The unit may be provided at an end of the container and/or within a seam of the container. The unit may include one or more connectors and/or a filtered connector. The one or more connectors may include a hardwired connector and/or USB connection and/or wireless connector and/or infra-red connector.

One or more edges of the second container part may be provided by a fold provided in a length of flexible conductor. One or more edges of the second container part may be provided by using stitches and/or adhesive to join two pieces of flexible conductor together. Preferably a section of conductor is folded across the seam in respect of one or more, and preferably all, the seams.

The second container part may be provided with one or more regions which have two, or more preferably three, layers of flexible conductor. The second container may be provided with one or more regions which have one, or more preferably two, layers of flexible connector.

The second container part may be provided with an electrical connector. The electrical connector may pass through the second container part to the surrounding environment. The connector may be provided in one of the faces of the second container part, preferably in the middle thereof. The electrical connector may be mounted on a rigid element, such as a plate. A part of the electrical connector may be sandwiched between a rigid element and another component, for instance a second rigid plate. The rigid element may be a disc. The flexible conductor may be mounted on a rigid element, for instance sandwiched between first and second plates.

The connector is preferably a filtered connector. The connector preferably provides electromagnetic shielding, ideally of a level of at least 40 dB, more preferably of at least 50 dB and ideally of at least 60 dB.

The container is preferably adapted to receive a mobile telecommunications device. The mobile telecommunications device may provide for one or two way communication or provision of electromagnetic radiation. The mobile telecommunication device may be a mobile phone, satellite phone, laptop computer, computer, printer, digital camera, video game console, wireless local area network device, Wi-Fi device, personal area network device, wireless personal area network device, Bluetooth device, personal digital assistants, pocket computers, palmtop computers, global positioning system device, web browsers, portable media players, radio transmitting and/or receiving device.

The first aspect of the invention may include any of the options, possibilities and features set out elsewhere in this document, including in the other aspects of the invention.

According to a second aspect of the invention we provide a method of isolating a telecommunication device, the method comprising introducing the device to a first container part of a container;

the container comprising:
a first container part and a second container part, the first container part being accessed from the second container part through a first seal, the first seal having an open state and a closed state, the second container part being accessed from the environment around the container through a second seal, the second seal having an open state and a closed state, the first container part and second container part, at least in part being formed of a flexible electrical conductor to provide electromagnetic shielding;

the method including the device being introduced to the first container part of the container with the first seal and the second seal in the open state, one or both of the first and second seals then being placed in the closed state to isolate the device from external electromagnetic radiation.

The method may use a container according to any of the features, options or possibilities set out elsewhere in this document.

The method may include providing an electrical link, more preferably a data transfer link, in the second container part, normally after the device has been introduced to the first container part. Preferably the second seal is provided in the open state and the first seal is provided in the closed state whilst the link is introduced.

The link may be connected to an electrical connector which passes through the second container part to the environment. The link may be connected with the first seal in the closed state and the second seal in the open or closed state. The link may be connected by manipulation through the wall of the second container part. The link may be connected by manipulation through the second seal in its open state. Before the first seal is changed to the open state, the second seal is preferably put in the closed state. With the first seal in the open state, the link is preferably connected to the device. The link may pass through the first seal to the first container part. The device may be moved to the second container part.

The device may be interrogated. The interrogation may take place through the connector and link, preferably data transfer link. The connector may be connected to a further link, for instance one linking an interrogation device to the connector. The second seal is preferably provide in the closed state during interrogation.

The method may include providing an electrical link in the first container part, normally after the device has been introduced to the first container part. Preferably the second seal is provided in the closed state and the first seal is provided in the open state whilst the link is introduced from the second container part. The link may have been introduced to the second container part with the first seal closed and the second seal open.

The link may be connected to an electrical connector which passes through the first container part to the environment. The link may be connected with the first seal in the open closed state, potentially with the second seal in either the open or closed state. The link may be connected with the first seal in either the closed or opened state and with the second seal in the closed state. The link may be connected by manipulation through the wall of the second container part and/or first container part. Before the first seal is changed to the open state, the second seal is preferably put in the closed state.

The device may be interrogated. The interrogation may take place through the connector and link, preferably data transfer link. The connector may be connected to a further link, for instance one linking an interrogation device to the connector.

The second aspect of the invention may include any of the options, possibilities and features set out elsewhere in this document, including in the other aspects of the invention.

According to a third aspect of the invention we provide a container, the container comprising a first container part, the first container part being accessed through a first seal, the first seal having an open state and a closed state, the first container part, at least in part, being formed of an electrical conductor to provide electromagnetic shielding, the first seal comprising a first magnet and a second magnet which are closer together in the closed state than in the open state.

The third aspect of the invention may include any of the features, options or possibilities set out elsewhere in this document.

One, preferably both, of the magnets may be rectilinear in profile. One, preferably both magnets may be of rectangular cross-section. One, preferably both magnets may have a length greater than their width and/or greater than their height. One, preferably both magnets may be strip magnets. One, preferably both magnets may be between 10 cm and 30 cm long. Preferably both magnets are of the same shape. Preferably both magnets are of the same dimensions.

One, preferably both magnets may extend along the full length of the opening sealed by the seal. Preferably a magnet is provide on each of two opposing sides of the opening.

One, preferably both magnets may be flexible. One, preferably both magnets may bendable.

Preferably the electrical conductor is flexible, at least in part. Preferably the electric conductor is formed over a fabric, at least in part.

Preferably the electrical conductor extends across the outside side of the magnet. Preferably the electrical conductor extends across the top side of the magnet. Preferably the electrical conductor extends across the inside side of the magnet. Preferably the electrical conductor extends around the outside, top and inside of the magnet. Preferably the electrical conductor extends around the ends of the magnet. Preferably the electrical conductor wraps around the magnet. A part, for instance the end of the electrical conductor may be attached to another part of the electrical conductor, ideally to enclose the magnet. Preferably both magnets are provided in the same way.

A second container part may be provided, preferably connected to the first container part via the first seal. The second container part is preferably provided with a seal, the second seal. The second seal may be provided at the opposite end of the second container part to the first seal. The second seal may have any of the features or options provided above. The first seal and the second seal are preferably provided with same structure.

According to a fourth aspect of the invention we provide a seal, the seal comprising a first magnet and a second magnet which are closer together in the closed state than in the open state.

The fourth aspect of the invention may include any of the features, options or possibilities set out elsewhere in this document, particularly those for the seal provided in the third aspect.

According to a fifth aspect of the invention we provide a method of isolating a telecommunication device, the method comprising introducing the device to a first container part of a container;

the container comprising:
a first container part, the first container part being accessed through a first seal, the first seal having an open state and a closed state, the first container part, at least in part, being formed of an electrical conductor to provide electromagnetic shielding, the first seal comprising a first magnet and a second magnet which are closer together in the closed state than in the open state;

the method including the device being introduced to the first container part of the container with the first seal in the open state, the first seal then being placed in the closed state to isolate the device from external electromagnetic radiation.

The fifth aspect of the invention may include any of the features, options or possibilities set out elsewhere in this document.

Various embodiments of the invention will now be described, by way of example only, and with reference to the accompanying drawings in which:

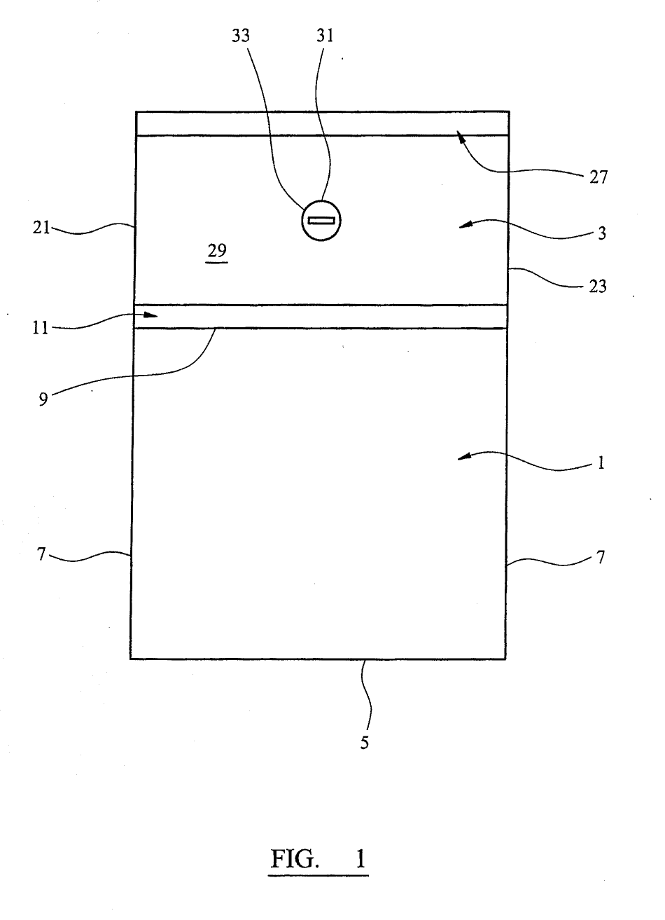

FIG. 1 is a perspective view of a container according to one embodiment of the invention;

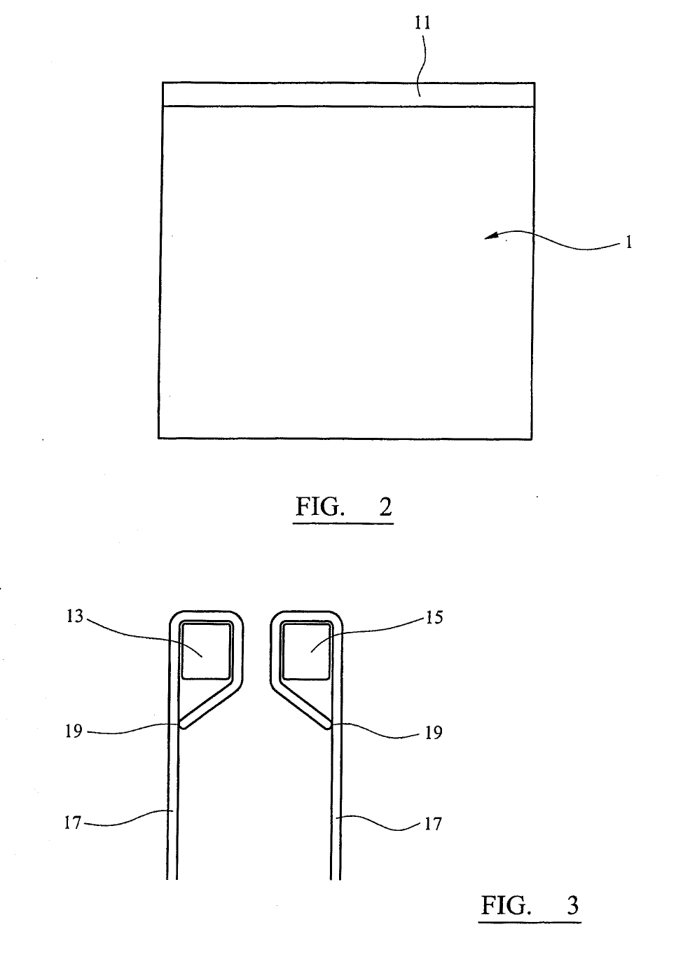

FIG. 2 is a perspective view of a container according to another embodiment of the present invention;

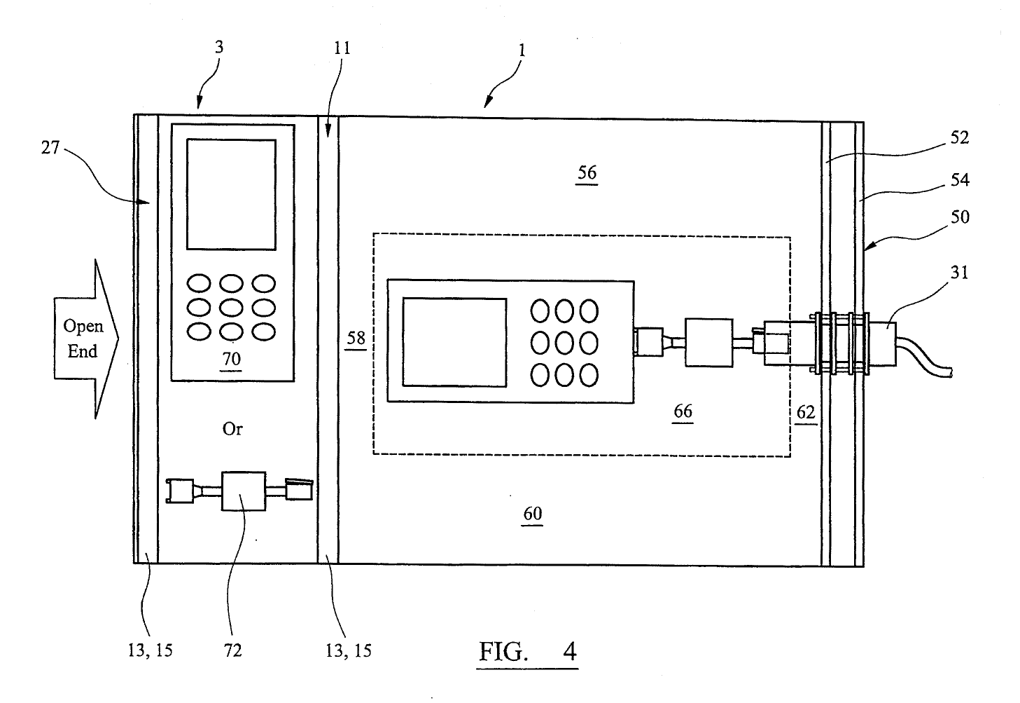

FIG. 3 is a cross-section through a seal for use in either embodiment of the present invention;

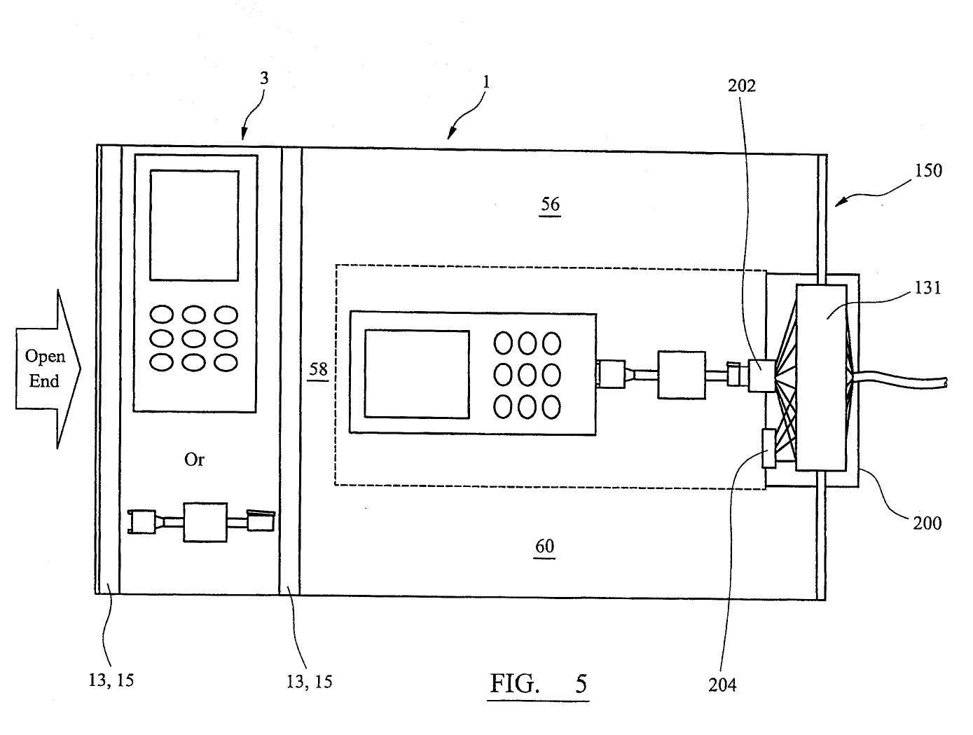

FIG. 4 is a perspective view of a container according to a further embodiment of the present invention;

FIG. 5 is a perspective view of a container according to a still further embodiment of the present invention.

The design illustrated in FIG. 1 features a first container part 1 and second container part 3. The edge 5 of the first container part 1 is formed by folding a panel of fabric in half. The edges 7 of the first container part 1 are then formed by stitching the edges of the panel halves together. The seams may be single or double stitched. The edges 7 are folded over, although other approaches could be taken, to eliminate the risk of electromagnetic waves passing through the seam. The other edge 9 is provided with an openable and closeable first seal 11.

The first seal 11 is formed of a first strip magnet 13 and a second strip magnet 15 in opposition to one another. The edge 17 of each half of the panel of fabric extends around the outside of the strip magnetic 13, 15, passes round the top of it and down the inside, before being joined to itself at seam 19. This configuration is illustrated in FIG. 3.

The first seal 11 can be opened by pulling the strip magnets 13, 15 apart and closed by placing the strip magnets 13, 15 in proximity with one another. The strip magnets 13, 15 assist the closing. The wrapping of the fabric around the strip magnets 13, 15 again eliminates the risk of electromagnetic waves passing through the first seal 11 when it is closed.

Connected to the first container part 1 via the first seal 11 is the second container part 3. The second container part 3 is formed by folding a panel of fabric in half to give folded edge 21. Edge 23 is formed by stitching the panel sides together, again with the fabric folded over to obscure the seam. The other edge of the second container part 3 is provided with a second seal 27. This is formed in the same manner as the first seal 11.

Provided in the middle of the panel 29 is a connector 31. The connector 31 is a filtered connector of the type designed to provide an electrical connection through a barrier to electrical noise. The seam 33 around the connector is again folded over to prevent electromagnetic waves passing through the join.

The alternative embodiment of the invention illustrated in FIG. 2 is equivalent in structure to the first container part 1 of the FIG. 1 embodiment. It lacks the second container part 3, but includes a first seal 11 of the same type.

When a mobile telecommunication device is found and there is a need to isolate it, either of the embodiments can be used. The first seal 11 is opened and the mobile telecommunication device is passed through it and into the first container part 1. The first seal 11 is then closed and the device is fully isolated. The design of the first seal 11 presents a significant improvement of prior seal designs, such a hook and eye fastenings, which fail to isolate fully the device.

In the case of the FIG. 1 embodiment, obviously the device is passed through the second seal 27 and second container part 3 to reach the first container part 1. Once there, the device is fully isolated.

To enable interrogation of the device, a connection has to be made to it, but without forming an ariel for the device. The first embodiment of the invention is particularly useful in this respect. The aim is achieved by inspecting the device to determine the appropriate link to join the device to the connector 31 in the panel of the second container part 3. A number of different links may be provided to enable a wide variety of different devices, with different output connector forms, to be connected to the common connector 31.

To provide the connection, the second seal 27 is opened and the selected link is introduced into the second container part 3. By reaching through the opening provided by the second seal 27 in its open state and/or by manipulating the link by virtue of the flexible nature of the material, the link is connected to the connector 31. Throughout, the first seal 11 is closed and so the device is fully isolated.

The second seal 27 is then closed before any step is taken to connect the link to the device. Once the second seal 27 is closed and the device is isolated by that and the fabric, the first seal 11 can then be opened. The link can then be manipulated to pass it through the open first seal 11 and connect it to the device. Throughout, the device is fully isolated. With the connection made, the device can be interrogated and information be extracted. There is no risk of undesirable external contact with the device being made, however. Throughout, the attenuation factor is effective to isolate the signals from the telecommunication device.

In the case of the third embodiment, the same principles are deployed in a slightly different configuration. In this case, the filtered connector 31 is provided at an end 50 of the first container part 1. The end is formed by two oval aluminium plates 52, 54 with an axially aligned through aperture in each to receive the connector 31. A flange on the connector is sandwiched between the two plates 52, 54, to keep it in place. The two plates 52, 54 are held together by releasable fasteners, such as nuts and bolts. Another difference with this embodiment is the use of double layers of fabric to form the whole of the second container part 3, to wrap around the strip magnets 13, 15 and to provide the rear panel and regions 56, 58, 60, 62 of the front panel of the fabric. A single layer of fabric is used to form region 66 of the front panel. This allows greater visibility of the mobile telecommunication device and/or easier manipulation, when present in this part of the first container part 1.

The fabric itself, assembly, strip magnets 13, 15 and other components are provided in the same manner as for the FIG. 1 embodiment.

In use, the FIG. 4 embodiment is used in a slightly different sequence. The device 70 is introduced through second seal 27, second container part 3 and first seal 11, into the first container part 1. The seal 11, at least, is then closed to isolate the device 70. The correct link 72 for connecting the device 70 to the filtered connector 31 can then be identified and be introduced into the second container part 3. The second seal 27 is then closed, before the first seal 11 is opened and the link 72 can be manipulated through into the first container part 1. Once there, the link 70 and device 72 can be manipulated to join the two together and to join the link 72 to the connector 31. The device 70 is then ready for interrogation.

In the case of the FIG. 5 embodiment, the same general structure is employed as is used in the FIG. 4 form. The filtered connector 131 is provided at an end 150 of the first container part 1. The filter connector 131 is included in a unit 200 which is mounted in a wall formed by joining the layers of fabric together. The unit 200 also includes a choice of onward connection to the mobile telecommunications device. As shown, the connection is made through a hardwired data transfer link 202. The option of a USB cable link 204 is also provided. The same or different links 204 may provide Bluetooth, infra-red or other wireless connection within the first container part 1. With this embodiment triple layers of fabric are provided to form the whole of the second container part 3, to wrap around the strip magnets 13, 15 and to provide the rear panel and regions 56, 58, 60 of the front panel of the fabric. A double layer of fabric is used to form region 66 of the front panel. This allows greater visibility of the mobile telecommunication device and/or easier manipulation, when present in this part of the first container part 1.

A suitable fabric for use in the present invention is provided by a woven or knitted fabric, with the nylon coated in silver. The resulting material is stretchy and flexible. The fabric weighs around 40 g·m⁻², uses silver of 99% purity and provides effective shielding over the frequency range 30 MHz to 3 GHz.

1. A container, the container comprising a first container part, the first container part being accessed through a first seal, the first seal having an open state and a closed state, the first container part, at least in part, being formed of an electrical conductor to provide electromagnetic shielding, the first seal comprising a first magnet and a second magnet which are closer together in the closed state than in the open state.

2. A container according to claim 1 in which both of the magnets are flexible.

3. A container according to claim 1 in which the electrical conductor is flexible.

4. A container according to claim 1 in which the electric conductor is formed over a fabric.

5. A container according to claim 1 in which the electrical conductor wraps around the magnet.

6. A container according to claim 1 in which the container includes a second container part connected to the first container part via the first seal.

7. A container according to claim 6 in which the second container part is provided with a second seal, the second seal being provided at the opposite end of the second container part to the first seal.

8. A container, preferably according to claim 1, the container comprising a first container part and a second container part, the first container part being accessed from the second container part through a first seal, the first seal having an open state and a closed state, the second container part being accessed from the environment around the container through a second seal, the second seal having an open state and a closed state, the first container part and second container part, at least in part being formed of an electrical conductor to provide electromagnetic shielding.

9. A container according to claim 8 in which the first container part is larger than the second container part.

10. A container according to claim 1 in which the first seal provides electromagnetic shielding in the closed state and/or the second seal provides electromagnetic shielding in the closed state.

11. A container according to claim 1 in which the electrical conductor provides electromagnetic shielding of at least 4 OdB

12. A container according to claim 1 in which the first container part is provided with one or more regions which have two or three layers of flexible conductor.

13. A container according to claim 12 in which one face of the first container part is provided at least partially with one layer where other parts are provided with two layers or with two layers where other parts are provided with three layers.

14. A container according to claim 1 in which the connector is a filtered connector.

15. A container according to claim 1 in which the container is adapted to receive a mobile telecommunications device.

16. A method of isolating a telecommunication device, the method comprising introducing the device to a first container part of a container; the container comprising: a first container part, the first container part being accessed through a first seal, the first seal having an open state and a closed state, the first container part, at least in part, being formed of an electrical conductor to provide electromagnetic shielding, the first seal comprising a first magnet and a second magnet which are closer together in the closed state than in the open state;
the method including the device being introduced to the first container part of the container with the first seal in the open state, the first seal then being placed in the closed state to isolate the device from external electromagnetic radiation.

17. A method of isolating a telecommunication device, preferably according to claim 16, the method comprising introducing the device to a first container part of a container; the container comprising: a first container part and a second container part, the first container part being accessed from the second container part through a first seal, the first seal having an open state and a closed state, the second container part being accessed from the environment around the container through a second seal, the second seal having an open state and a closed state, the first container part and second container part, at least in part being formed of a flexible electrical conductor to provide electromagnetic shielding; the method including the device being introduced to the first container part of the container with the first seal and the second seal in the open state, one or both of the first and second seals then being placed in the closed state to isolate the device from external electromagnetic radiation.

18. A method according to claim 17 in which a data transfer link is provided in the first container part after the device has been introduced to the first container part, the second seal being provided in the closed state and the first seal being provided in the open state whilst the link is introduced from the second container part.

19. A method according to claim 18 in which the link is introduced to the second container part with the first seal closed and the second seal open.

20. A method according to any claim 16 in which the device is interrogated.

21. A method according to claim 20 in which the interrogation takes place through the connector and link.
